(19) United States
(12) Patent Application Publication
(10) Pub. No.: US 2010/0270671 A1
(43) Pub. Date: Oct. 28, 2010

(54) MANIPULATING FILL PATTERNS DURING ROUTING

(75) Inventors: Alan Holesovsky, Fort Collins, CO (US); John David Corbeil, JR., Fort Collins, CO (US)

Correspondence Address: MENDELSOHN, DRUCKER, & ASSOCIATES, P.C., 1500 JOHN F. KENNEDY BLVD., SUITE 405, PHILADELPHIA, PA, 19102, US

(73) Assignee: LSI CORPORATION, Milpitas, CA (US)

(21) Appl. No.: 12/431,154

(22) Filed: Apr. 28, 2009

(51) Int. Cl. H01L 23/52; G06F 17/50

(52) U.S. Cl. 257/734; 716/5; 257/E23.141

(57) ABSTRACT

A CAD tool that supports an overlay-enabling operating mode. After the overlay-enabling operating mode is entered, the layout-editing facility permits modifications to the interconnect structure of an integrated circuit that is being designed regardless of whether a particular modification interferes with an existing pattern of metal fill. For example, a new signal wire can be added to electrically connect two specified points in the layout in a manner that causes the wire to cross over one or more metal-fill tiles. The CAD tool then modifies the fill pattern to get rid of any design-rule violations caused by the modifications to the interconnect structure by removing and/or modifying one or more fill tiles.

### CROSS-REFERENCE TO RELATED APPLICATIONS

The subject matter of this application is related to the subject matter of U.S. patent application Ser. No. 12/339,407, filed Dec. 19, 2008, and entitled “Fill Patterning for Symmetrical Circuits,” which is incorporated herein by reference in its entirety.

### BACKGROUND

1. Field of the Invention

The present invention relates generally to die-planarization techniques and, more specifically but not exclusively, to placement of fill tiles in an interconnect structure of an integrated circuit (IC).

2. Description of the Related Art

This section introduces aspects that may help facilitate a better understanding of the invention(s). Accordingly, the statements of this section are to be read in this light and are not to be understood as admissions about what is in the prior art or what is not in the prior art.

Chemical-mechanical polishing (CMP) is a planarization technique that is widely used in IC fabrication. A surface of the die subjected to CMP undergoes (i) chemical reactions induced by a slurry and (ii) mechanical abrasion by a CMP pad. Although CMP pads and slurries have improved significantly over the years, the smoothness of the resulting die surface is still not perfect and significant post-CMP surface-topography variations can occur for some circuit-layout patterns. As successive metal and dielectric layers are being deposited over a die and subjected to CMP during the fabrication of an interconnect structure for the IC, the post-CMP surface-topology variations translate into thickness variations within the interconnect levels and inter-level dielectric (ILD). These thickness variations might be detrimental to the IC yield and/or performance because they disturb lithographic imaging and throw off the electrical parameters (such as resistance and/or capacitance) of the interconnect structure.

One design-for-manufacturability (DFM) technique that improves surface planarity uses insertion of special metal patterns (often referred to as fills, dummies, or waffles) into the circuit layout to make the density distribution over the die as uniform as possible. Since the CMP material-removal rate is a function of local material density, the metal fill helps to reduce the above-described thickness variations. However, if not appropriately managed, insertion of metal fill might significantly complicate the IC-design process.

### SUMMARY

Disclosed herein are various embodiments of a CAD tool that supports an overlay-enabling operating mode. After the overlay-enabling operating mode is entered, the layout-editing facility permits modifications to the interconnect structure of an integrated circuit that is being designed regardless of whether a particular modification interferes with an existing pattern of metal fill. For example, a new signal wire can be added to electrically connect two specified points in the layout in a manner that causes the wire to cross over one or more metal-fill tiles. The CAD tool then identifies to the user any design-rule violations caused by the modifications to the interconnect structure and modifies the fill pattern to get rid of the violations. Advantageously, embodiments of the invention can be used to implement changes to an interconnect structure having a metal-fill pattern inserted therein in a relatively efficient, substantially error-proof, and minimally intrusive manner.

According to one embodiment, provided is a computer-implemented method of generating a representation of an integrated circuit having the steps of: (A) inserting an initial fill pattern into an initial interconnect structure of the integrated circuit to generate an initial representation of the integrated circuit; and (B) modifying the initial interconnect structure to generate a first modified representation of the integrated circuit having a modified interconnect structure, wherein at least one track of the modified interconnect structure interferes with one or more tiles of the initial fill pattern.

According to another embodiment, provided is a machine-readable medium having encoded thereon program code, wherein, when the program code is executed by a machine, the machine implements the above-specified method of generating a representation of an integrated circuit.

According to yet another embodiment, provided is a machine-readable medium having encoded thereon program code corresponding to a representation of the integrated circuit generated by implementing on a computer the above-specified method of generating a representation of an integrated circuit, wherein, when the program code is executed by a fabrication machine, the fabrication machine fabricates a physical embodiment of the integrated circuit.

### BRIEF DESCRIPTION OF THE DRAWINGS

Other aspects, features, and benefits of various embodiments of the invention will become more fully apparent, by way of example, from the following detailed description and the accompanying drawings, in which:

FIGS. 1A-B illustrate a prior-art integrated circuit having a multilevel interconnect structure;

FIGS. 2A-B schematically show two representative fill patterns that can be used in various embodiments of the invention; and

FIGS. 3A-C illustrate a fill-placement method according to one embodiment of the invention.

### DETAILED DESCRIPTION

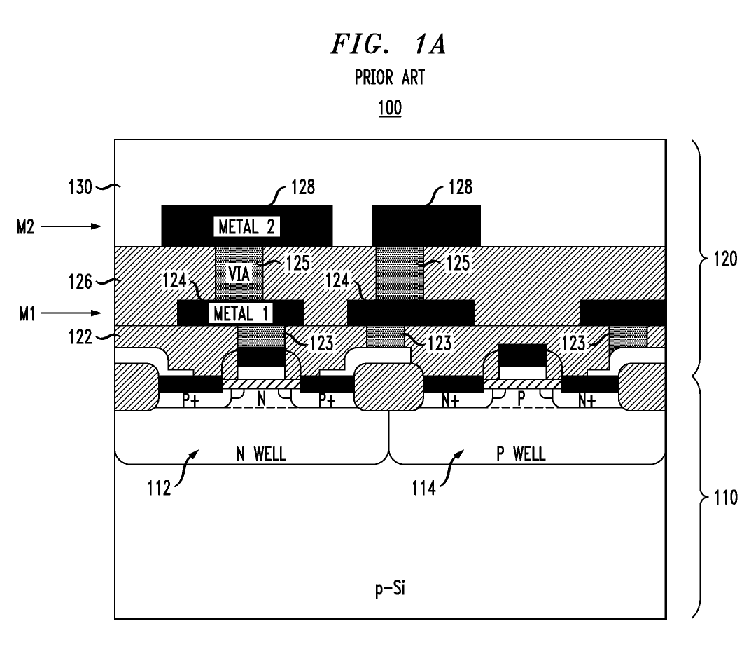

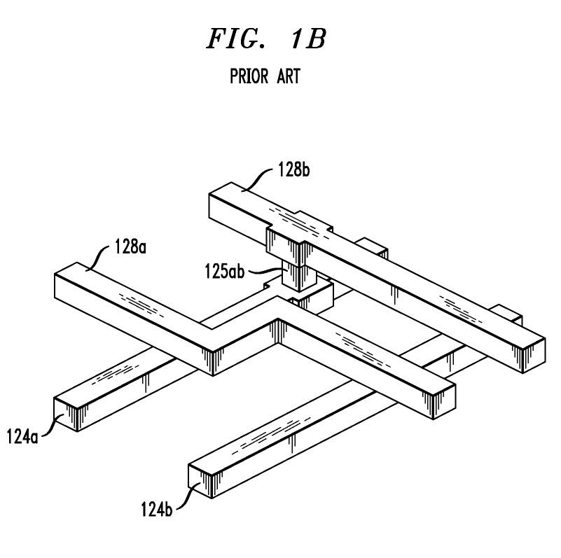

FIGS. 1A-B illustrate a prior-art integrated circuit (IC) 100 having a multilevel interconnect structure 120. More specifically, FIG. 1A shows a schematic cross-sectional view of IC 100. FIG. 1B shows a perspective three-dimensional cutout view of a portion of interconnect structure 120.

Referring to FIG. 1A, IC 100 has a semiconductor wafer 110 in which various circuit elements, such as a p-channel field-effect transistor (p-FET) 112 and an n-channel field-effect transistor (n-FET) 114, have been formed as known in the art. Interconnect structure 120 serves to transport voltages and/or currents to and from the various circuit elements of wafer 110. In FIG. 1A, interconnect structure 120 is shown as having two levels (M1 and M2) of metallic conductors, such as conductors 124 in level M1 and conductors 128 in level M2, surrounded by inter-level-dielectric (ILD) layers 122, 126, and 130. ILD layer 122 has metal-filled vias 123 that provide electrical connections between certain M1 conductors 124 and the corresponding electrical terminals in the circuit elements of wafer 110. ILD layer 126 has metal-filled vias 125 that provide electrical connections between certain M1 conductors 124 and certain M2 conductors 128. Each of ILD layers 122, 126, and 130 might comprise two or more sub-layers (not explicitly shown in FIG. 1A) made of different dielectric materials. One skilled in the art will appreciate that interconnect structure 120 might have one or more additional levels of metallic conductors and the corresponding ILD layers with vias, all located above (i.e., at a greater distance from wafer 110 than) ILD layer 130.

FIG. 1B shows a representative layout of M1 conductors 124 and M2 conductors 128 in IC 100, with ILD layers 122, 126, and 130 and wafer 110 intentionally not shown for clarity. Conductors 124 and 128 comprise a plurality of substantially planar metal tracks that might have L-shaped turns similar to that of conductor 128a. Some of the conductors, such as M1 conductor 124a and M2 conductor 128b, might be electrically connected by one or more vias, such as via 125ab.

Design-for-manufacturability (DFM) specifications typically stipulate a density range for each interconnect level. For example, the DFM specifications might say that, for interconnect level M1, the metal density should be between 20% and 80% of a maximum density, where the maximum density is the density corresponding to a contiguous metal layer having no gaps in it. The DFM specifications usually have specific density constraints for each interconnect level. As already indicated above, the density specifications help to reduce the post-CMP surface-topology variations in the die.

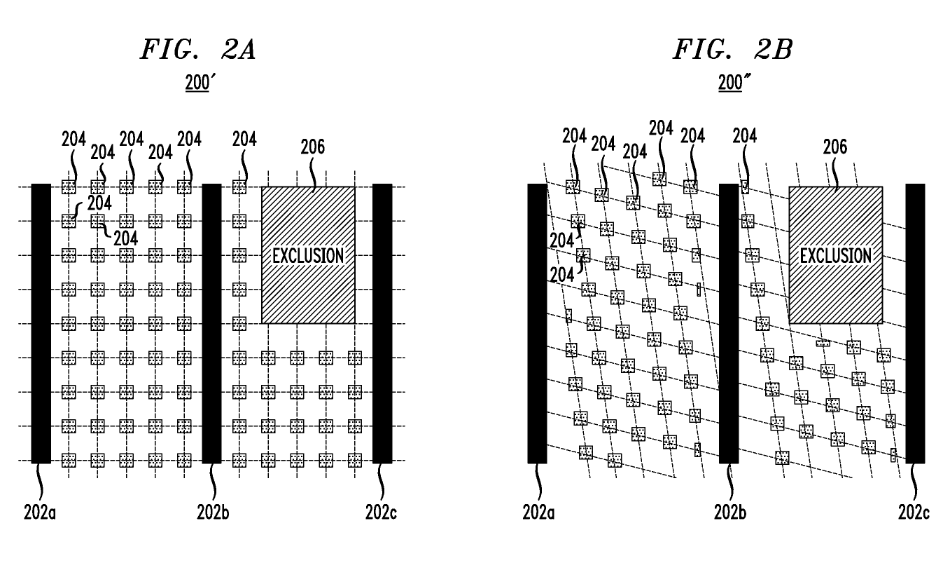

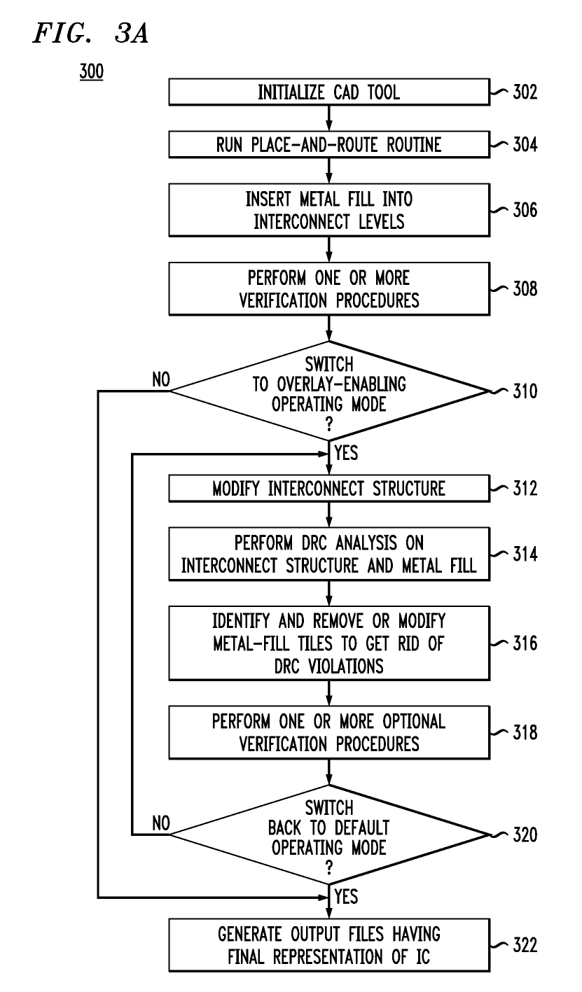

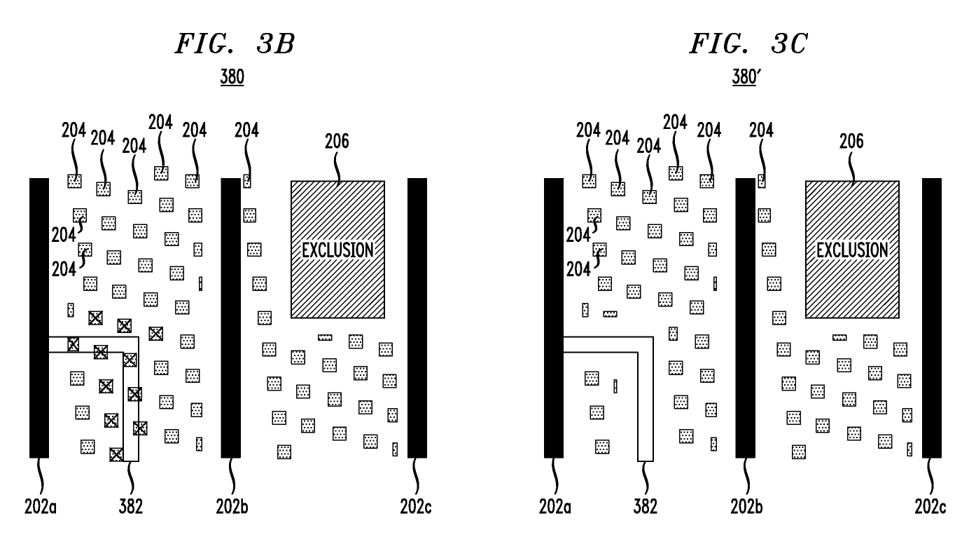

FIGS. 2A-B schematically show two representative fill patterns that can be used to meet DFM density specifications according to certain embodiments of the invention. More specifically, each of FIGS. 2A-B shows a top view of a single interconnect level 200 of a multilevel interconnect structure that can be used, e.g., to replace interconnect structure 120 in IC 100. Interconnect level 200 has (i) metal tracks 202a-c and (ii) a plurality of square or rectangular, electrically floating or grounded tiles 204 of metal fill placed between the metal tracks. The placement of metal-fill tiles 204 is subject to certain fill-placement rules that are described in more detail below in reference to FIG. 3. For example, the fill-placement rules might define exclusion areas, such as an exclusion area 206, within which no metal-fill tiles 204 are present. The fill-placement rules might specify a guard distance for metal tracks 202 and ban the placement of metal-fill tiles 204 closer to the metal tracks than the guard distance, etc.

In interconnect level 200, metal-fill tiles 204 are placed at intersections of grid lines. The embodiment of interconnect level 200 shown in FIG. 2A (and labeled 200′) is filled with tiles 204 using two orthogonal sets of grid lines (indicated by the dashed lines in FIG. 2A), with one of the sets being aligned with metal tracks 202. In contrast, the embodiment of interconnect level 200 shown in FIG. 2B (and labeled 200″) is filled with tiles 204 using two non-orthogonal sets of grid lines. The type of metal fill corresponding to interconnect level 200″ is often referred to as “staggered fill” or “random fill.” Staggering the tile shapes might have one or more of the following benefits: accurately predictable capacitive coupling to any metal track in an adjacent interconnect level, uniform duty cycle during mask write, and reduced shear stress during the fabrication process.

FIGS. 3A-C illustrate a fill-placement method 300 according to one embodiment of the invention. More specifically, FIG. 3A shows a flowchart of method 300. FIGS. 3B-C schematically show layouts of a representative interconnect level 380 that are produced at certain steps of method 300. In general, method 300 is implemented as part of a software package or suite for computer-aided design (CAD) of ICs.

At step 302, a CAD tool that employs method 300 is initialized. Such initialization usually includes, but is not limited to loading up the appropriate software into the computer memory and having appropriate input files ready for processing.

At step 304, a place-and-route routine of the CAD tool is executed to generate an initial representation of an IC that is being designed. As the name implies, the place-and-route routine comprises two subroutines: a placement subroutine and a routing subroutine. The placement subroutine of step 304 assigns locations within the IC core area for various circuit components. The assignment is usually performed while several circuit metrics are being optimized to ensure that the IC meets certain performance specifications. Such optimization might include: (i) minimizing the total chip area; (ii) satisfying timing constraints; (iii) keeping circuit-element density/congestion below a specified level; (iv) optimizing power consumption/distribution, e.g., to avoid hot spots, etc.

The routing subroutine of step 304 adds wires, tracks, and vias to generate an interconnect structure that properly connects the circuit components having locations assigned by the placement subroutine. Representative tasks of the routing subroutine might include: (i) electrically connecting all terminals assigned to the same net; (ii) avoiding electrical shorts between different nets; and (iii) obeying specified design rules. In addition, the routing subroutine is usually expected to ensure that the routed circuit meets timing specifications, does not have significant crosstalk problems, does not suffer from antenna effects, etc. The interconnect structure generated by the routing subroutine usually has two or more interconnect levels that are analogous to levels M1 and M2 of FIG. 1A.

At step 306, fill patterns are inserted into various interconnect levels of the interconnect structure generated at step 304. The fill-pattern insertion of step 306 follows certain fill-placement rules. In one embodiment, the following six fill-placement rules might be used:
(A) Use fill tiles of one or more specified shapes: Rectangular tiles 204 (see FIG. 2) represent one example of a possible shape. In principle, any suitable shape or shapes can be used. Each shape is usually available in two or more (incrementally changing) sizes;
(B) Observe inter-tile spacing: The inter-tile spacing parameters are usually selected from two or more options that can be different for different interconnect levels;
(C) Maintain a selected guard distance between a conducting track and adjacent fill tiles: The guard distance is usually selected from two or more specified values that can be different for different interconnect levels;
(D) Attain a targeted effective density within the interconnect level: Typically, DFM specifications provide a density range and/or a preferred effective density value. The effective density is usually calculated using a discrete window, e.g., 100×100 μm², that is stepped, in some fashion, across the interconnect level. For each location of the window, the average density over the window is calculated and compared with the target value. Adjustments to the fill pattern are made as necessary to attain the desired density characteristics;
(E) Use staggered or non-staggered fill tiles: FIGS. 2A and 2B show representative examples of staggered and non-staggered fill tiles, respectively; and
(F) Avoid placing fill tiles so that they are located directly below and/or directly above the conducting tracks that carry sensitive signals in a specified number of adjacent interconnect levels.
   In alternative embodiments, different and/or additional fill-placement rules might similarly be used.

At step 308, one or more verification procedures are performed for the circuit representation generated at step 306. Verification procedures are usually intended to confirm that the physical, structural, and behavioral aspects of the circuit meet the specifications. Verification of the physical aspects usually includes running a design-rule check (DRC). Verification of the structural aspects usually includes performing a layout-versus-schematic (LVS) analysis. Verification of the behavioral aspects usually includes performing timing verification and/or an event-driven logic simulation.

Design rules usually include a series of parameters provided by a semiconductor manufacturer that enable the designer to verify the correctness of a mask set. Design rules are specific to a particular semiconductor manufacturing process. A design rule set might specify certain geometric and connectivity restrictions to ensure sufficient margins to account for variability in semiconductor manufacturing processes and ensure that the physical embodiment of the circuit works correctly. A main objective of a DRC analysis is to achieve a high overall yield and reliability for the particular design. To meet this objective, DRC software has evolved from performing relatively simple geometric measurements and Boolean checks to also incorporating more complex procedures that can modify existing features, insert new features, and check the entire design for process limitations, such as layer density. Fill-placement rules are usually part of the design rules checked during a DRC analysis. While DRCs do not guarantee that the design will operate as intended, they do verify that the corresponding physical structure meets the process constraints for a given design type and process technology.

An LVS analysis determines whether the particular design corresponds to the originally intended schematic or circuit diagram. LVS checking software recognizes the drawn shapes of the layout that represent various electrical components of the circuit, as well as the connections between them. The software then compares them with the intended schematic or circuit diagram. Typical errors discovered during an LVS analysis include: (i) shorts, wherein two or more wires that should not be connected together are connected; (ii) opens, wherein wires or components that should be connected are left dangling or only partially connected; (iii) component mismatches, wherein components of an incorrect type have been used; (iv) missing components, wherein an expected component has been left out of the layout; (v) property errors, wherein a component has a wrong size, not corresponding to the schematic; etc.

A main objective of timing verification is to traverse the circuit network and, for every possible input and output signal, find the worst-case-scenario (e.g., the slowest) signal-propagation path. Timing verification might also be implemented to consider other properties of the design that are deemed pertinent to accurate determination of signal-propagation delays. For example, MOS transistors can function bi-directionally, meaning that a relatively large array of MOS transistors can present exponentially as large a number of paths. Hence, user-specified directionality information can be used to reduce the number of paths that need actually be considered.

Suppose now that, after steps 304-308 have been performed, a decision is made to change the interconnect structure generated at step 304. Possible reasons for the change might include (i) an engineering change order (ECO) received from the customer; (ii) a change to the library of standard circuit cells/elements; (iii) a timing failure discovered at step 308; (iv) an LVS error discovered at step 308; and/or (v) a DRC violation discovered at step 308. Depending on the underlying reason(s), a required change to the interconnect structure might rank anywhere from slight to substantial.

When changing the interconnect structure of a circuit representation that already has one or more fill patterns inserted therein, it is often desirable to minimize changes to the metal fill. For example, the metal-fill patterns generated at step 306 already comply with the corresponding, often very complex, specifications and satisfy the fill-placement rules, and any metal-fill changes might result in a non-compliant layout. The impact of the metal fill on the timing of signals has been analyzed and accounted for at step 308, and any metal-fill changes might significantly change the timing. A process of removing the metal fill generated at step 306, generating new metal-fill patterns after the required changes to the interconnect structure have been effected, and rerunning the verification procedures similar to those of step 308 is usually disadvantageously time- and effort-consuming.

A typical prior-art approach to making changes to the metal fill while effecting a change to the interconnect structure generally relies on manual modifications. More specifically, a typical prior-art CAD tool does not permit modifications of the interconnect structure that conflict with the already-existing metal fill. As a result, the metal-fill tiles that interfere with the intended change in the interconnect structure have to be painstakingly identified, tile by tile, by the human designer and manually removed from the layout before the intended change to the interconnect structure can be effected. Only after the corresponding metal-fill-free area is created does the prior-art CAD tool allow the intended change to the interconnect structure to be made. For example, the human designer can route a new conducting track through the freed area. Disadvantageously, this prior-art process is relatively slow, error prone, and/or intrusive to the design. In particular, it is relatively easy to fall into the trap of deleting too many or too few metal-fill tiles while creating the requisite fill-free area.

Method 300 addresses the above-indicated problems by providing a special CAD-tool operating mode, in which the layout-editing facility ignores potential conflicts between the intended modifications to the interconnect structure and the existing metal fill. Hereafter, this special CAD-tool operating mode is referred to as an overlay-enabling operating mode. After an overlay-enabling operating mode is entered, the layout-editing facility will permit modifications to the interconnect structure regardless of whether a particular modification interferes with the existing metal fill. For example, if a new signal wire needs to be added to electrically connect two specified points in the layout in a manner that causes the wire to cross over one or more metal-fill tiles, then the layout-editing facility will disregard the corresponding conflicts between the new wire and the existing metal fill and allow the new wire to be added. Representative processing modules corresponding to the overlay-enabling operating mode are further described below.

At step 310 of method 300, it is determined whether the CAD tool is to be switched to an overlay-enabling operating mode. As already indicated above, transition to the overlay-enabling operating mode might be prompted by a decision to change the interconnect structure generated at step 304. The decision to change might be made for any reason, e.g., one or more of the above-indicated reasons. If it is determined that a switch to the overlay-enabling operating mode is to be made, then the processing of method 300 is directed to step 312. Otherwise, the processing of method 300 is directed to step 322.

At step 312, the interconnect structure is modified to meet the objectives of the change. The modified interconnect structure usually has overlays and/or conflicts with the metal fill generated at step 306.

FIG. 3B shows a top view of interconnect level 380 of a representative modified interconnect structure produced at step 312. More specifically, interconnect level 380 is produced by adding a metal track 382 to level 200″ shown in FIG. 2B. As can be seen in FIG. 3B, metal track 382 overlaps and/or conflicts with several metal-fill tiles 204. However, the layout-editing facility of the CAD tool ignores these overlaps and conflicts because the CAD tool is operating in the overlay-enabling operating mode. As a result, the layout-editing facility allows metal track 382 to be added to level 200″ (FIG. 2B), thereby producing interconnect level 380 (FIG. 3B).

Referring back to FIG. 3A, at step 314 of method 300, a DRC analysis is performed for the circuit representation having the interconnect structure produced at step 312 and the metal fill generated at step 306. Any possible overlays and/or conflicts between the interconnect structure produced at step 312 and the metal fill generated at step 306 manifest themselves as the corresponding DRC violations.

At step 316, metal-fill tiles corresponding to the DRC violations discovered at step 314 are identified and removed or modified to get rid of the DRC violations. For example, FIG. 3B shows each of the metal-fill tiles 204 corresponding to a DRC violation discovered during the DRC analysis of step 314 as being marked with a diagonal cross in the tile. In particular, at least some of the marked metal-fill tiles 204 violate fill-placement rule (C) described above in reference to step 306. FIG. 3C shows a top view of interconnect level 380′ that is produced at step 316 from interconnect level 380 of FIG. 3B. As can be seen from the comparison of FIGS. 3B-C, interconnect level 380′ has the metal-fill tiles 204 marked by a diagonal cross in FIG. 3B removed or modified to get rid of the corresponding DRC violations identified at step 314, e.g., violations of fill-placement rule (C).

Although FIGS. 3B-C illustratively show metal-fill modifications for a single level of the interconnect structure, one of ordinary skill in the art will appreciate that the addition of metal track 382 might also introduce one or more DRC violations in one or more interconnect levels that are adjacent to interconnect level 380. For example, the presence of metal track 382 might cause metal-fill tiles in an interconnect level next to interconnect level 380 to violate fill-placement rule (F) described above in reference to step 306. Other DRC violations can similarly be triggered by the addition of metal track 382. Accordingly, metal-fill tiles corresponding to the DRC violations discovered at step 314 in other interconnect levels will be similarly identified and removed or modified at step 316 to get rid of those DRC violations.

At step 318, one or more verification procedures similar to those of step 308 can optionally be performed for the circuit representation generated at step 316. For example, one or more of an LVS analysis, timing verification, and an event-driven logic simulation can be performed. The number and type of the verification procedures performed at step 318 usually depend on the extent of modifications introduced during the overlay-enabling operating mode. In many situations, the execution of step 318 involves running an LVS analysis only. Oftentimes, step 318 can be skipped altogether. If LVS and/or timing errors are found at step 318, then the circuit representation is modified to get rid of those errors.

One skilled in the art will appreciate that the above-described order of steps 314-318 is merely exemplary and can be changed in various embodiments of method 300. For example, the verification procedures corresponding to steps 314 and 318 can be completed prior to making any changes to the present circuit representation. Similarly, the modifications corresponding to steps 316 and 318 can be performed together to address all pertinent errors discovered during the verification procedures. In general, metal-fill tiles corresponding to the errors can be identified to the user and removed and/or modified as appropriate, automatically or manually.

At step 320, it is determined whether the CAD tool is to be switched back to a default operating mode. If not, then steps 312-318 are repeated as necessary to accommodate any subsequent changes to the interconnect structure. Said subsequent changes might include modifications to the same net and/or a different net. Otherwise, the overlay-enabling operating mode is exited and the processing of method 300 is directed to step 322.

At step 322, output files that encode a final representation of the IC are generated. The final representation might have the modified interconnect structure and the modified fill pattern produced, e.g., at steps 316 and 318. The files generated at step 322 are usually transferred to and used at a fabrication facility to make a set of masks and fabricate a physical embodiment of the final representation of the IC.

While this invention has been described with reference to illustrative embodiments, this description is not intended to be construed in a limiting sense. For example, fill tiles having any suitable shapes can be used. Although various embodiments of the invention have been described in reference to metal-fill tiles, other suitable materials (such as poly-silicon, a silicon oxide, a metal oxide, or a metal nitride) can similarly be used to form the fill tiles. The fill tiles can be electrically floating or tied-off (i.e., connected to an electrical terminal held at a specified potential). Various fill-placement rules that differ from the six placement rules described in reference to FIG. 3 can be used in various embodiments of method 300. Various modifications of the described embodiments, as well as other embodiments of the invention, which are apparent to persons skilled in the art to which the invention pertains are deemed to lie within the principle and scope of the invention as expressed in the following claims.

As used in the claims, the term “interconnect structure” refers to the functional metal that carries signals, currents, and/or electric potentials to and/or from various circuit elements in the IC. In contrast, the term “fill pattern” refers to a plurality of fill tiles. In general, an interconnect structure and a fill pattern should be considered as separate and distinct entities, even though a box drawn around the interconnect structure might spatially enclose the fill pattern. The term “interfere” should be interpreted as indicative of a layout, in which the geometric and functional relationship between the interconnect structure and the metal fill causes the corresponding circuit representation to have one or more DRC, LVS, timing, and/or other pertinent violations and/or errors. An overlap between the interconnect structure and one or more tiles of the metal fill pattern is just one example of such interference.

The present invention can be embodied in the form of methods and apparatuses for practicing those methods. The present invention can also be embodied in the form of program code embodied in tangible media, such as floppy diskettes, CD-ROMs, hard drives, or any other machine-readable storage medium, wherein, when the program code is loaded into and executed by a machine, such as a computer, the machine becomes an apparatus for practicing the invention. The present invention can also be embodied in the form of program code, for example, whether stored in a storage medium, loaded into and/or executed by a machine, or transmitted over some transmission medium or carrier, such as over electrical wiring or cabling, through fiber optics, or via electromagnetic radiation, wherein, when the program code is loaded into and executed by a machine, such as a computer, the machine becomes an apparatus for practicing the invention.

Unless explicitly stated otherwise, each numerical value and range should be interpreted as being approximate as if the word “about” or “approximately” preceded the value of the value or range.

It will be further understood that various changes in the details, materials, and arrangements of the parts which have been described and illustrated in order to explain the nature of this invention may be made by those skilled in the art without departing from the scope of the invention as expressed in the following claims.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

Throughout the detailed description, the drawings, which are not to scale, are illustrative only and are used in order to explain, rather than limit the invention. The use of terms such as height, length, width, top, bottom, is strictly to facilitate the description of the invention and is not intended to limit the invention to a specific orientation. For example, height does not imply only a vertical rise limitation, but is used to identify one of the three dimensions of a three dimensional structure as shown in the figures. Such “height” would be vertical where the electrodes are horizontal but would be horizontal where the electrodes are vertical, and so on. Similarly, while all figures show the different layers as horizontal layers such orientation is for descriptive purpose only and not to be construed as a limitation.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

Transistors are typically shown as single devices for illustrative purposes. However, it is understood by those with skill in the art that transistors will have various sizes (e.g., gate width and length) and characteristics (e.g., threshold voltage, gain, etc.) and may consist of multiple transistors coupled in parallel to get desired electrical characteristics from the combination. Further, the illustrated transistors may be composite transistors.

What is claimed is:

1. A computer-implemented method of generating a representation of an integrated circuit, the method comprising:
(A) inserting an initial fill pattern into an initial interconnect structure of the integrated circuit to generate an initial representation of the integrated circuit; and
(B) modifying the initial interconnect structure to generate a first modified representation of the integrated circuit having a modified interconnect structure, wherein at least one track of the modified interconnect structure interferes with one or more tiles of the initial fill pattern.

2. The method of claim 1, wherein at least one track of the modified interconnect structure overlaps with one or more tiles of the initial fill pattern.

3. The method of claim 1, wherein:
a CAD tool that implements the method has a default operating mode and a second operating mode;
the default operating mode enables step (A); and
the second operating mode enables step (B).

4. The method of claim 3, further comprising switching the CAD tool from the default operating mode to the second operating mode after performing step (A), but prior to performing step (B).

5. The method of claim 1, further comprising:
(C) removing or modifying at least one tile of the initial fill pattern to generate a second modified representation of the integrated circuit having a modified fill pattern, wherein the second modified representation complies with a specified set of design rules.

6. The method of claim 5, wherein the specified set of design rules comprises a set of fill-placement rules.

7. The method of claim 5, wherein the specified set of design rules prohibits a superposition of a track of an interconnect structure and a fill tile.

8. The method of claim 5, wherein:
the initial interconnect structure has two or more interconnect levels;
step (B) comprises modifying a selected level of the two or more interconnect levels; and
step (C) comprises removing or modifying at least one tile of the fill pattern in a different level of the two or more interconnect levels.

9. The method of claim 5, wherein step (C) comprises:
(C1) performing a design-rule-check (DRC) analysis for the first modified representation;
(C2) identifying one or more tiles of the initial fill pattern corresponding to a DRC violation; and
(C3) removing or modifying the one or more identified tiles to generate the second modified representation having the modified fill pattern.

10. The method of claim 5, further comprising:
(D) performing one or more verification procedures for the second modified representation to compare at least one of physical, structural, and behavioral aspects of the second modified representation with a set of specifications.

11. The method of claim 5, further comprising repeating steps (B) and (C) one or more times, wherein the modified interconnect structure corresponding to the second modified representation of a most recent occurrence of step (C) serves as the initial interconnect structure for a next occurrence of step (B).

12. The method of claim 5, further comprising generating one or more data files that encode the modified interconnect structure and the modified fill pattern.

13. The method of claim 12, further comprising fabricating a physical embodiment of the integrated circuit using said one or more data files.

14. A physical embodiment of the integrated circuit fabricated using the method of claim 5 and having the modified interconnect structure and the modified fill pattern.

15. The method of claim 1, further comprising executing a place-and-route routine to generate the initial interconnect structure.

16. The method of claim 1, further comprising performing one or more verification procedures for the initial representation to compare at least one of physical, structural, and behavioral aspects of the initial representation with a set of specifications.

17. A machine-readable medium, having encoded thereon program code, wherein, when the program code is executed by a machine, the machine implements the method of claim 1.

18. A machine-readable medium having encoded thereon program code corresponding to a representation of the integrated circuit generated by implementing on a computer the method of claim 1, wherein, when the program code is executed by a fabrication machine, the fabrication machine fabricates a physical embodiment of the integrated circuit.
